(19) United States
(12) Patent Application Publication
(10) Pub. No.: US 2025/0294943 A1
(43) Pub. Date: Sep. 18, 2025

(54) DISPLAY DEVICE, METHOD OF MANUFACTURING THE DISPLAY DEVICE, AND ELECTRONIC DEVICE INCLUDING THE DISPLAY DEVICE

(71) Applicant: Samsung Display Co., Ltd., Yongin-Si (KR)

(72) Inventors: Sunghwan KIM, Yongin-si (KR); Daehyun KIM, Yongin-si (KR)

(21) Appl. No.: 19/004,462

(22) Filed: Dec. 30, 2024

(30) Foreign Application Priority Data
Mar. 14, 2024 (KR) 10-2024-0035803

(51) Int. Cl. H10H 29/49; H10H 29/01

(52) U.S. Cl. CPC H10H 29/49; H10H 29/012

(57) ABSTRACT

A display device includes a substrate including a main area including a display area, a sub area spaced apart from the main area in a first direction, and a plurality of bending areas connecting the main area and the sub area, a display panel in the display area on the substrate, and a printed circuit board attached to the sub area.

### CROSS-REFERENCE TO RELATED APPLICATION

This application claims priority to Korean Patent Application No. 10-2024-0035803, filed on Mar. 14, 2024, and all the benefits accruing therefrom under 35 U.S.C. § 119, the content of which in its entirety is herein incorporated by reference.

### BACKGROUND

### Field

The present disclosure relates to a display device, a method of manufacturing the display device, and an electronic device including the display device. More specifically, the present disclosure relates to the display device that provides visual information, the method of manufacturing the display device, and the electronic device including the display device.

### Discussion of the Background

The demand for various forms of light-emitting display devices has increased as our information society has developed. Light emitting display devices are increasing being used not only in relatively large display devices such as laptops, televisions, and monitors but also in small devices such as electronic watches. However, as display devices become smaller and luminance of the display devices increases, wiring in the display devices has become smaller and closer to each other, increasing resistance, which causes heat generation that can be a problem when the product is used. To solve this problem, attempts are being made to lower resistance and increase a spacing between wires.

### SUMMARY

One aspect of the present disclosure is to provide a display device with improved reliability.

Another aspect of the present disclosure is to provide a method of manufacturing the display device.

Still another aspect of the present disclosure is to provide an electronic device including the display device.

A display device according to an embodiment of the present disclosure may include a substrate including a main area including a display area, a sub area spaced apart from the main area in a first direction, and a plurality of bending areas connecting the main area and the sub area, a display panel disposed in the display area on the substrate and a printed circuit board attached to the sub area.

In an embodiment, the bending areas may include a first bending area and a second bending area, the second bending area being spaced apart from the first bending area in a second direction at a non-zero angle to the first direction.

In an embodiment, a width of the first bending area may be greater than a width of the second bending area.

In an embodiment, the display device may further include first power wires extending from the printed circuit board and connecting a first power source to the display panel and second power wires extending from the printed circuit board and connecting a second power source different from the first power source to the display panel, and each of the first power wires and the second power wires may overlap the bending areas.

In an embodiment, each of the first power wires and the second power wires may overlap the first bending area.

In an embodiment, the first power wires may overlap the first bending area, and the second power wires may overlap the second bending area.

In an embodiment, a voltage level of the first power source may be greater than a voltage level of the second power source.

In an embodiment, at least one of the bending areas may include three or more bending lines.

In an embodiment, the first bending area may include a first bending line, a second bending line spaced apart from the first bending line, and a third bending line between the first bending line and the second bending line. The first bending line and the second bending line may not overlap in a plan view.

In an embodiment, the display device may further include a driver disposed in the sub area and driving the display panel, and the driver may be mounted in the sub area using a chip-on plastic (COP) method.

In an embodiment, each of the sub area and the bending areas may at least partially overlap the main area in a plan view.

In an embodiment, at least one of the bending areas may be between the main area and the sub area.

In an embodiment, at least one of the bending areas may be below the sub area.

In an embodiment, the substrate may include plastic.

In an embodiment, the display panel may have a circular shape in a plan view.

In an embodiment, the display panel may have a square shape in a plan view.

A method of manufacturing a display device according to an embodiment of the present disclosure may include providing a substrate including a main area including a display area, a sub area spaced apart from one side of the main area, and a plurality of bending areas connecting the main area and the sub area, forming a display panel in the display area of the substrate, attaching a printed circuit board to the sub area, and bending the bending areas.

In an embodiment, in bending the bending areas, at least one of the bending areas is bent two or more times.

In an embodiment, in bending the bending areas, each of the sub area and the bending areas may be bent to at least partially overlap the main area in a plan view.

In an embodiment, at least one of the bending areas may include a first bending line, a second bending line spaced apart from the first bending line, and a third bending line between the first bending line and the second bending line. The first bending line and the second bending line may be bent so as not to overlap in a plan view.

An electronic device according to an embodiment of the present disclosure may include a display device and a processor configured to drive the display device, and wherein the display device includes a substrate including a main area including a display area, a sub area spaced apart from the main area in a first direction, and a plurality of bending areas connecting the main area and the sub area, a display panel disposed in the display area on the substrate, and a printed circuit board attached to the sub area.

A display device may include a substrate including a main area including a display area, a sub area spaced apart from the main area in a first direction, and a plurality of bending areas connecting the main area and the sub area, a display panel disposed in the display area on the substrate, and a printed circuit board attached to the sub area.

Accordingly, arranging a plurality of bending areas between the main area and the sub area may increase spacing between power wires arranged in the bending areas. Accordingly, resistance to current flow in each of the power wires may be lowered. In addition, as the resistance of each of the power wires is lowered, heat generated from the display device may be reduced.

Aspects of the present disclosure are not limited to the above-described aspects, and embodiments of the present disclosure may be expanded in various ways without departing from a spirit and scope of the present disclosure.

### BRIEF DESCRIPTION OF THE DRAWINGS

The accompanying drawings illustrate example embodiments of the of the present disclosure.

FIG. 1 is a perspective view showing a display device according to an embodiment of the present disclosure.

FIG. 2 is a plan view showing a display device according to an embodiment of the present disclosure.

FIG. 3 is a plan view showing the display device of FIG. 2 after a bending process.

FIG. 4 is a plan view showing one embodiment of power wiring disposed on the substrate of FIG. 2.

FIG. 5 is a plan view showing another embodiment of power wiring disposed on the substrate of FIG. 2.

FIG. 6 is a cross-sectional view of a portion of an embodiment of the display device of FIG. 2 taken along line I-I′ of FIG. 2.

FIG. 7 is a cross-sectional view showing an embodiment of the display panel of FIG. 6.

FIG. 8 is a circuit diagram showing an example of a pixel in an embodiment of the display device of FIG. 2.

FIG. 9 is a cross-sectional view showing a bent portion an embodiment of the display device of FIG. 3.

FIG. 10 is a cross-sectional view showing another bent portion of an embodiment of the display device of FIG. 3.

FIGS. 11, 12, 13, 14, and 15 are plan views showing structures created during a method of manufacturing the display device of FIG. 1.

FIG. 16 is a plan view showing a display device according to another embodiment of the present disclosure.

FIG. 17 is a block-diagram showing an electronic device according to an embodiment of the disclosure.

FIG. 18 shows schematic views of electronic devices according to various embodiments of FIG. 17.

### DETAILED DESCRIPTION

Illustrative, non-limiting embodiments will be more clearly understood from the following detailed description in conjunction with the accompanying drawings.

In this specification, a plane may be defined by a first line and a second line that intersect, the first line extending a first direction D1 and the second line extending a second direction D2 that that is not parallel to the first direction D1. For example, the second direction D2 may be perpendicular to the first direction D1. In addition, a third direction D3 may be a normal direction of the plane. That is, the third direction D3 may be perpendicular to the plane defined by intersecting lines respectively extending in the first direction D1 and the second direction D2.

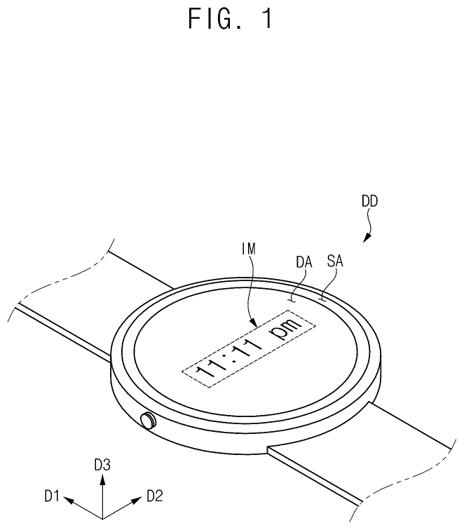

FIG. 1 is a perspective view showing a display device according to an embodiment of the present disclosure.

Referring to FIG. 1, a display device DD may include a display area DA and a peripheral area SA. The display area DA may be surrounded by the peripheral area SA.

The display area DA may be an area in which an image IM may be displayed by generating light or adjusting a transmittance of light from a light source through the display area DA. The peripheral area SA may be an area in which an image is not displayed. However, embodiments of the present disclosure are not necessarily limited thereto, and at least a portion of the peripheral area SA of the display device DD may display an image.

The display area DA may display a plurality of images IM. Users may receive information from the display device DD through the plurality of images IM.

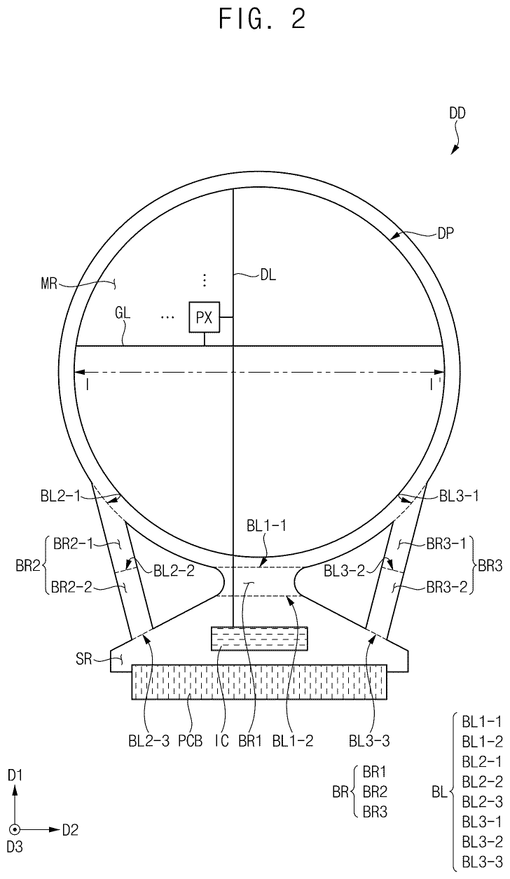

FIG. 2 is a plan view showing the structure of a display device according to an embodiment of the present disclosure.

Referring to FIG. 2, the display device DD may include a main area MR, bending areas BR, and a sub area SR, which may be arranged in order along a direction opposite to the first direction D1.

The main area MR may include the display area DA and the peripheral area SA shown in FIG. 1. The bending areas BR may connect the main area MR and the sub area SR and may include multiple separate bending areas BR1 to BR3 that are spaced apart from each other along the second direction D2. A display panel DP may be disposed in the display area DA of the main area MR. In an embodiment, the display panel DP may be circular shape in a plan view, as shown in FIG. 2. However, embodiments of the present disclosure are not necessarily limited thereto. The display panel DP may have other shapes such as an oval or a polygon in a plan view.

A plurality of pixels PX may be disposed in the main area MR. The pixels PX may be disposed in a matrix or rectangular array with rows and columns of the pixels PX extending along the first direction D1 and/or the second direction D2. The pixels PX may provide a visual image to a user of the display device DD. For example, the pixels PX may emit red, blue, and green light in a pattern that represents the image.

Data lines DL extending in the first direction D1 may be disposed in the main area MR. The data lines DL may be spaced apart from each other in the second direction D2. The data lines DL may apply data signals to the pixels PX.

Gate lines GL extending in the second direction D2 may be disposed in the main area MR. The gate lines GL may be spaced apart from each other in the first direction D1. The gate lines GL may apply gate signals to the pixels PX.

In an embodiment, the bending areas BR may include a first bending area BR1, a second bending area BR2, and a third bending area BR3. For example, the bending areas BR may include the first bending area BR1 connecting the main area MR and the sub area SR, the second bending area BR2 spaced apart from the first bending area BR1 in a direction opposite to the second direction D2, and the third bending area BR3 spaced apart from the first bending area BR1 in the second direction D2. However, embodiments of the present disclosure are not necessarily limited thereto. The bending areas BR may include two bending areas or four or more bending areas.

In an embodiment, each of the first bending area BR1, the second bending area BR2, and the third bending area BR3 may include two bending areas. For example, the second bending area BR2 may include a 2-1th bending area BR2-1 and a 2-2th bending area BR2-2. The third bending area BR3 may include a 3-1th bending area BR3-1 and a 3-2th bending area BR3-2. The 2-1th bending area BR2-1 and the 2-2th bending area BR2-2 may be adjacent to each other in the first direction D1, and the 3-1th bending area BR3-1 and the 3-2th bending area BR3-2 may be adjacent to each other in the first direction D1.

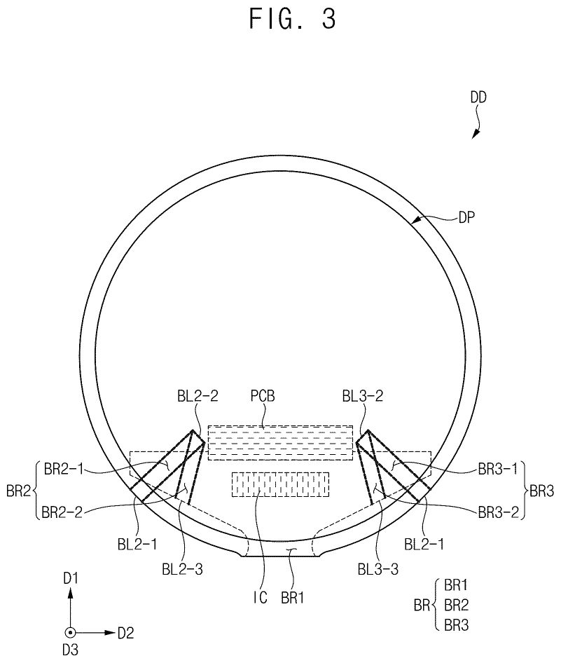

Each of the bending areas BR may include bending lines BL. As shown in FIG. 3, when the display device DD is bent, the display device DD may be bent along the bending lines BL.

In an embodiment, at least one of the bending areas BR may include three or more bending lines BL. For example, the first bending area BR1 may include a 1-1th bending line BL1-1 and a 1-2th bending line BL1-2. The second bending area BR2 may include a 2-1 bending line BL2-1, a 2-2th bending line BL2-2, and a 2-3th bending line BL2-3. The third bending area BR3 may include a 3-1th bending line BL3-1, a 3-2th bending line BL3-2, and a 3-3th bending line BL3-3. For example, the 2-2th bending line BL2-2 may be a line that separates the 2-1th bending area BR2-1 and the 2-2th bending area BR2-2. The 3-2th bending line BL3-2 may be a line that separates the 3-1th bending area BR3-1 and the 3-2th bending area BR3-2. Specifically, the 2-2th bending line BL2-2 may be between the 2-1 bending line BL2-1 and the 2-3th bending line BL2-3, and the 3-2th bending line BL3-2 may be between the 3-1th bending line BL3-1 and the 3-3th bending line BL3-3.

In an embodiment, a width of the first bending area BR1 in the second direction D2 may be greater than a width of the second bending area BR2 in the second direction D2. Specifically, as shown in FIG. 2, a width of the first bending area BR1 in the second direction D2 may be greater than a width of each of the second bending area BR2 and the third bending area BR3 in the second direction D2. Additionally, a width of each of the second bending area BR2 and the third bending area BR3 in the second direction D2 may be same. However, embodiments of the present disclosure are not necessarily limited thereto. A width of the first bending area BR1 in the second direction D2, a width of the second bending area in the second direction D2, and a width of the third bending area BR3 in the second direction D2 may all be the same. Alternatively, each of a width of the first bending area BR1 in the second direction D2, a width of the second bending area in the second direction D2, and a width of the third bending area BR3 in the second direction D2 may differ from each other.

A driver IC and a printed circuit board PCB may be disposed in the sub area SR. Specifically, the driver IC may be disposed in the sub area SR, and the printed circuit board PCB may be attached to one side of the sub area SR. The driver IC may be connected to the data lines DL to apply a data signal to the pixels PX. The printed circuit board PCB may be connected to power lines PSL to apply power to the pixels PX.

In an embodiment, the driver IC may be mounted in the sub area SR using a chip-on plastic (COP) method. That is, the substrate SUB of the display device DD may include plastic. For example, the substrate SUB may include polyimide, etc.

FIG. 3 is a plan view showing the display device of FIG. 2 after a bending process.

Referring to FIG. 3, when the display device DD is bent, the bending areas BR and the sub area SR may be disposed below the main area MR. In this case, the main area MR, the bending areas BR, and the sub area SR may overlap in a plan view. Specifically, each of the sub area SR and the bending areas BR may at least partially overlap the main area MR in a plan view.

In an embodiment shown in FIG. 3, when the display device DD is bent, the 2-1th bending area BR2-1 and the 2-2th bending area BR2-2 have a ‘V’ shape in a plan view. Likewise, the 3-1th bending area BR3-1 and the 3-2th bending area BR3-2 may have a ‘V’ shape in a plan view.

Since the second bending area BR2 has a ‘V’ shape in a plan view, an area where the 2-1th bending area BR2-1 and the 2-2th bending area BR2-2 overlap may be minimized. In addition, since the third bending area BR3 has a ‘V’ shape in a plan view, an area where the 3-1th bending area BR3-1 and the 3-2th bending area BR3-2 overlap may be minimized. Accordingly, the defects or malfunctions caused by electrical shorting of overlapping power wires PSL may be prevented or reduced.

In the example shown in FIG. 3, when the display device DD is bent, the 2-1 bending line BL2-1 and the 2-3th bending line BL2-3 may not overlap in a plan view. When the display device DD is bent, the 3-1th bending line BL3-1 and the 3-3th bending line BL3-3 may not overlap in a plan view.

In an embodiment, when the display device DD is bent, each of the bending areas BR may not overlap the driver IC and the printed circuit board PCB in a plan view. That is, each of the bending areas BR may be spaced apart from the driver IC and the printed circuit board PCB in a plan view.

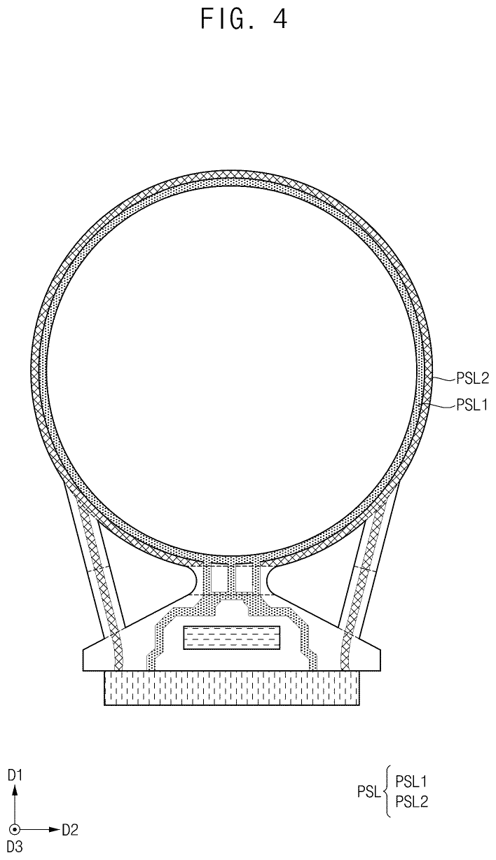

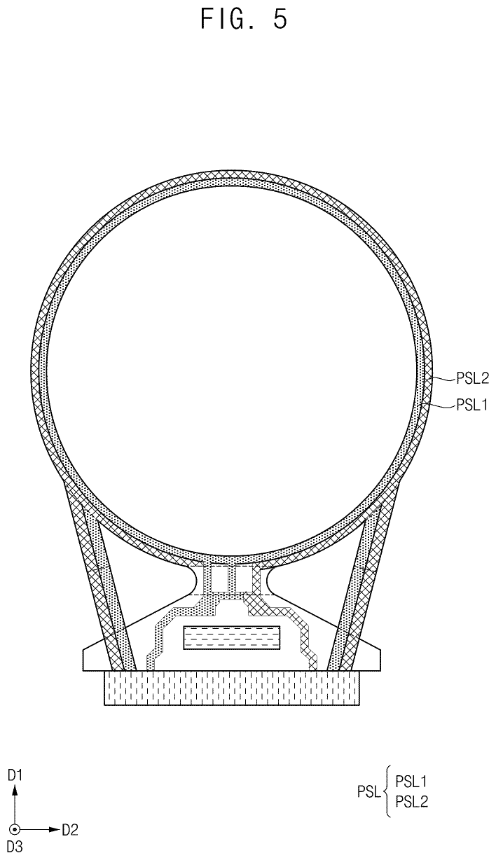

FIG. 4 is a plan view showing one embodiment of power wiring disposed on the substrate of the display device of FIG. 2. FIG. 5 is a plan view showing another embodiment of power wiring disposed on the substrate of the display device of FIG. 2.

Referring to FIGS. 4 and 5, the power wiring PSL extending from the printed circuit board PCB and applying a power voltage to the pixels PX may be disposed in the display device DD. The power wires PSL may include first power wires PSL1 for applying a first power voltage to the pixels PX and second power wires for applying a second power voltage to the pixels PX. For example, the first power voltage may be a driving voltage, and the second power voltage may be a common voltage. The first power wires PSL1 and the second power wires PSL2 may pass through the bending areas BR and may extend in the peripheral area (e.g., the peripheral area SA in FIG. 1).

In the embodiment shown in FIG. 4, each of the first power wires PSL1 and the second power wires PSL2 may overlap different bending areas BR. For example, the first power wires PSL1 may overlap the first bending area BR1, and the second power wires PSL2 may overlap the second bending area BR2 and the third bending area BR3. However, embodiments of the present disclosure are not necessarily limited thereto. The first power wires PSL1 may overlap not only the first bending area BR1 but also the second bending area BR2 and/or the third bending area BR3. The first power wires PSL1 and the second power wires PSL2 may overlap different bending areas BR, so that defects or malfunctions caused by electrical shorting between the first power wires PSL1 and the second power wires PSL2 may be prevented or reduced.

In an embodiment, as shown in FIG. 5, the first power wires PSL1 and the second power wires PSL2 may overlap same bending areas BR. For example, the first power wires PSL1 and the second power wires PSL2 may overlap the first to third bending areas BR1, BR2, and BR3. However, embodiments of the present disclosure are not necessarily limited thereto. The first power wires PSL1 may alternatively overlap the first bending area BR1 and the second bending area BR2, and the second power wires PSL2 may overlap the second bending area BR2 and the third bending area BR3.

Each of the first power wires PSL1 and the second power wires PSL2 may pass through the bending areas BR and overlap the main area MR. Specifically, the first power wires PSL1 and the second power wires PSL2 may surround the display panel DP in the main area MR and overlap the peripheral area SA.

In an embodiment, a level of the first power voltage applied by the first power wires PSL1 may be greater than a level of the second power voltage applied by the second power wires PSL2.

Since the plurality of bending areas BR, which extend between the main area MR and the sub area SR, may be separated from each other, intervals between the power lines PSL disposed in the bending areas BR may become greater. Accordingly, a resistance to current flow of each of the power supply lines PSL may be lower. In addition, with the resistance of each of the power wires PSL being lower, heat generated from the display device DD may be reduced.

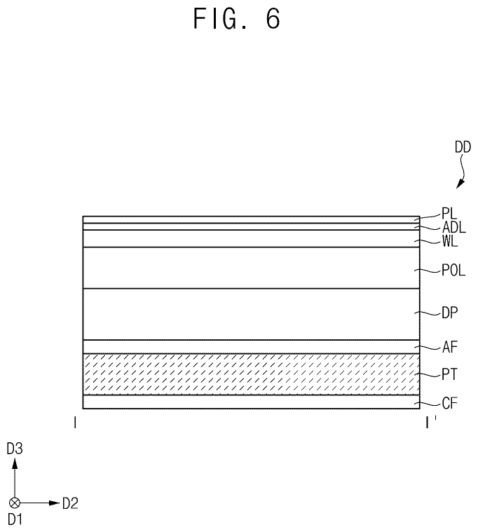

FIG. 6 is a cross-sectional view of an embodiment of the display device of FIG. 2 taken along line I-I′ of FIG. 2.

Referring to FIG. 6, the display device DD may include a cover film CF, a plate PT, an adhesive film AF, a display panel DP, a polymer layer POL, a window layer WL, an adhesive ADL, and a protective film PL.

The cover film CF may be disposed on a back of the display device DD. The cover film CF may alleviate the effects of external shock that the display device DD may receive. The cover film CF may include at least one of sponge, expanded foam, thermoplastic polyurethane, and polydimethylacrylamide. These materials may be used alone or in combination with each other. Alternatively, the cover film CF may include a light blocking material. Accordingly, the cover film CF may absorb light incident on a back of the display device DD.

The plate PT may be on the cover film CF. The plate PT may structurally support the display to prevent external forces from bending the display panel DP. That is, the plate PT may maintain the display panel DP in a relatively flat state even when an external force is applied from outside the display device DD. The plate PT may include a rigid or semi-rigid material. For example, the plate PT may include at least one of iron, chromium, carbon, nickel, silicon, manganese, and molybdenum. These materials may be used alone or in combination with each other. However, embodiments of the present disclosure are not necessarily limited thereto.

The adhesive film AF may be on the plate PT. The adhesive film AF may attach the plate PT and the display panel DP. For example, the adhesive film AF may include at least one of pressure sensitive adhesive (PSA), optical clear adhesive (OCA), and optical clear resin (OCR). However, embodiments of the present disclosure are not necessarily limited thereto.

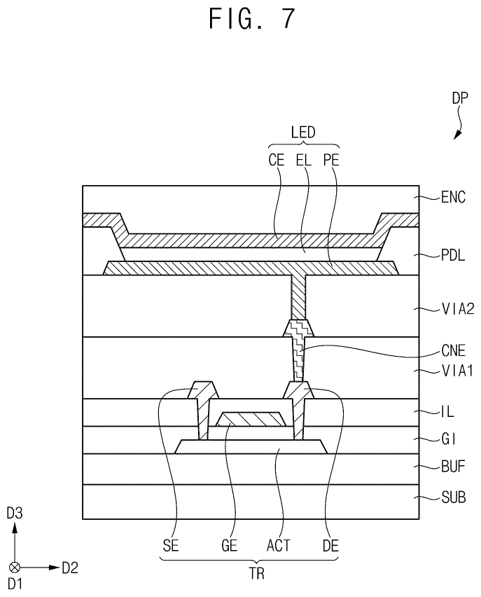

The display panel DP may be on the adhesive film AF. The display panel DP may generate light based on a provided signal. Accordingly, the display panel DP may provide a visual image to a user of the display device DD. The display panel DP is described further below with reference to FIG. 7.

The polymer layer POL may be on the display panel DP. The polymer layer POL may attach the display panel DP and the window layer WL. In addition, the polymer layer POL may support the window layer WL to prevent the window layer WL from sagging and protect the display panel DP from external shocks, etc. The polymer layer POL may have a single-layer or multi-layer structure.

The window layer WL may be on the polymer layer POL. The window layer WL may cover a front surface of the display device DD and protect the display panel DP. The window layer WL may include a substantially transparent material. For example, the window layer WL may contain glass or plastic. However, embodiments of the present disclosure are not necessarily limited thereto.

The adhesive layer ADL may be on the window layer WL. The adhesive layer ADL may attach the window layer WL and the protective film PL. The adhesive layer ADL may include a transparent material. For example, the adhesive layer ADL may include at least one of pressure sensitive adhesive (PSA), optical clear adhesive (OCA), and optical clear resin (OCR). However, embodiments of the present disclosure are not necessarily limited thereto.

The protective film PL may be on the adhesive layer ADL. The protective film PL may protect the window layer WL from external impacts and/or scratches. For example, the protective film PL may include a base layer and a hard coating layer. However, embodiments of the present disclosure are not necessarily limited thereto. The protective film PL may further include a low refractive index layer, an anti-reflection layer, and/or an anti-fingerprint layer.

FIG. 7 is a cross-sectional view of an embodiment of the display panel of FIG. 6.

Referring to FIGS. 1, 6, and 7, the display panel DP may include the substrate SUB, a buffer layer BUF, a gate insulating layer GI, a transistor TR, an interlayer insulating layer IL, a connection electrode CNE, a first via layer VIA1, a second via layer VIA2, a light emitting diode LED, a pixel defining layer PDL, and an encapsulation layer ENC. The transistor TR may include an active layer ACT, a gate electrode GE, a source electrode SE, and a drain electrode DE. The light emitting diode LED may include a pixel electrode PE, a light emitting layer EL, and a common electrode CE.

The substrate SUB may include a glass substrate, a metal substrate, a plastic substrate, etc. However, embodiments of the present disclosure are not necessarily limited thereto, and the substrate SUB may be an inorganic layer, an organic layer, or a composite material layer.

The buffer layer BUF may be on the substrate SUB. The buffer layer BUF may prevent impurities such as oxygen and moisture from penetrating the substrate SUB and overlying structures. The buffer layer BUF may include an inorganic insulating material.

The active layer ACT may be on the buffer layer BUF. The active layer ACT may include a semiconductor such as an oxide semiconductor, a silicon semiconductor, an organic semiconductor, etc. For example, the oxide semiconductor may include indium (In), gallium (Ga), tin (Sn), zirconium (Zr), vanadium (V), hafnium (Hf), cadmium (Cd), germanium (Ge), chromium (Cr), titanium (Ti), and zinc (Zn). The silicon semiconductor may include amorphous silicon, polycrystalline silicon, etc. The active layer ACT may include a source region, a drain region, and a channel region located between the source region and the drain region.

The gate insulating layer GI may be on the buffer layer BUF. Specifically, the gate insulating layer GI may cover the active layer ACT on the buffer layer BUF. The gate insulating layer GI may include an inorganic insulating material. In an embodiment, the gate insulating layer GI may cover the entirety of the display area DA and the peripheral area SA.

The gate electrode GE may be disposed on the gate insulating layer GI. The gate electrode GE may at least partially overlap the channel region of the active layer ACT. The gate electrode GE may include a conductive material such as a metal, alloy, conductive metal nitride, conductive metal oxide, or transparent conductive material. Examples of the conductive material that may be used in the gate electrode GE may include gold (Au), silver (Ag), aluminum (Al), platinum (Pt,) nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), an alloy containing aluminum, alloy containing silver, ab alloy containing copper, an alloy containing molybdenum, aluminum nitride (AlN), tungsten nitride (WN), titanium nitride (TiN), chromium nitride (CrN), tantalum nitride (TaN), strontium ruthenium oxide (SrRuO), zinc oxide (ZnO), indium tin oxide (ITO), tin oxide (SnO), indium oxide (InO), gallium oxide (GaO), indium zinc oxide (IZO), etc. These materials may be used alone or in combination with each other. The gate electrode GE may have a single-layer structure or a multi-layer structure including a plurality of conductive layers.

The interlayer insulating layer IL may be on the gate electrode GE. Specifically, the interlayer insulating layer IL may be on the gate insulating layer GI and cover the gate electrode GE on the gate insulating layer GI. The interlayer insulating layer IL may include an inorganic insulating material.

The source electrode SE and the drain electrode DE may be on the interlayer insulating layer IL. Each of the source electrode SE and the drain electrode DE may extend into openings through the interlayer insulating layer IL and the gate insulating layer GI to connected to the active layer ACT. For example, the source electrode SE may contact the source region of the active layer ACT, and the drain electrode DE may contact the drain region of the active layer ACT. Each of the source electrode SE and the drain electrode DE may include a conductive material. The active layer ACT, the gate electrode GE, the source electrode SE, and the drain electrode DE may form the transistor TR.

The first via layer VIA1 may be on the source electrode SE and the drain electrode DE. Specifically, the first via layer VIA1 may be on the interlayer insulating layer IL and cover the source electrode SE and the drain electrode DE on the interlayer insulating layer IL. The first via layer VIA1 may include an organic insulating material. In an embodiment, the first via layer VIA1 may be formed only in the display area DA and a portion of the peripheral area SA adjacent to the display area DA.

The connection electrode CNE may be on the first via layer VIA1 and may extend through an opening in the first via layer VIA1 to contact the transistor TR, e.g., the drain electrode DE. The connection electrode CNE may transmit a signal transmitted from the transistor TR to the light emitting diode LED. The connection electrode CNE may include metal, alloy, metal nitride, conductive metal oxide, transparent conductive material, etc. These materials may be used alone or in combination with each other. However, embodiments of the present disclosure are not necessarily limited thereto.

The second via layer VIA2 may be on the connection electrode CNE. Specifically, the second via layer VIA2 may be on the first via layer VIA1 and cover the connection electrode CNE. The second via layer VIA2 may include substantially the same material as the first via layer VIA1.

The pixel electrode PE may be on the second via layer VIA2. The pixel electrode PE may include a conductive material. The pixel electrode PE may extend through an opening in the second via layer VAI2 to contact the connection electrode CNE, which connects to the drain electrode DE. Accordingly, the pixel electrode PE may be electrically connected to the transistor TR.

The pixel defining layer PDL may be on the pixel electrode PE. For example, the pixel defining layer PDL may define an opening that exposes at least a portion of the pixel electrode PE. The pixel defining layer PDL may include an inorganic insulating material or an organic insulating material.

The light emitting layer EL may be on the pixel electrode PE. Specifically, the light emitting layer EL may be within the opening defined by the pixel defining layer PDL. That is, the light emitting layer EL may be surrounded by the pixel defining layer PDL. The light emitting layer EL may include at least one of organic light emitting material and/or quantum dots. However, embodiments of the present disclosure are not necessarily limited thereto.

The common electrode CE may be on the light emitting layer EL. The common electrode CE may also be on the pixel defining layer PDL. That is, the common electrode CE may extend continuously on the light emitting layer EL and the pixel defining layer PDL. The common electrode CE may include a conductive material. The light emitting layer EL may emit light based on a voltage difference between the pixel electrode PE and the common electrode CE.

The encapsulation layer ENC may be on the common electrode CE. The encapsulation layer ENC may include at least one inorganic encapsulation layer and at least one organic encapsulation layer. In an embodiment, the inorganic encapsulation layer and the organic encapsulation layer may be alternately stacked. For example, the organic encapsulation layer may include a cured polymer such as polyacrylate, epoxy resin, or silicone resin. For example, the inorganic thin film may include silicon oxide, silicon nitride, silicon carbide, aluminum oxide, tantalum oxide, hafnium oxide, zirconium oxide, titanium oxide, etc.

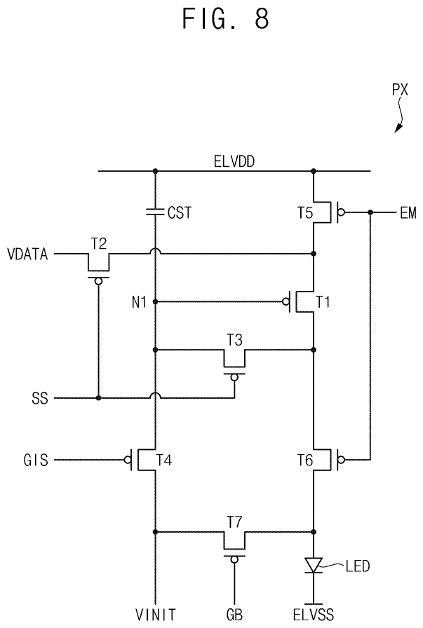

FIG. 8 is a circuit diagram showing an example of a pixel in an embodiment of the display device of FIG. 2.

Referring to FIG. 8, each of the pixels PX may include first, second, third, fourth, fifth, sixth, and seventh transistors T1, T2, T3, T4, T5, T6, and T7, a capacitor CST, and the light emitting diode LED.

The first transistor T1 may include a gate electrode, a first electrode, and a second electrode. The gate electrode of the first transistor T1 may be connected to a node N1, which also connects to a second electrode of the capacitor CST, a first electrode of the third transistor T3, and a first electrode of the fourth transistor T4. The first electrode of the first transistor T1 may be connected to a second electrode of the fifth transistor T5. The second electrode of the first transistor T1 may be connected to a second electrode of the third transistor T3.

The second transistor T2 may include a gate electrode, a first electrode, and a second electrode. A scan signal SS may be applied to the gate electrode of the second transistor T2. A data voltage VDATA may be applied to the first electrode of the second transistor T2. The second electrode of the second transistor T2 may be connected to the first electrode of the first transistor T1.

The third transistor T3 may include a gate electrode, the first electrode, and a second electrode. The scan signal SS may be applied to the gate electrode of the third transistor T3. The first electrode of the third transistor T3 may be connected to the node N1, which connects to the second electrode of the capacitor CST, the gate electrode of the first transistor, and the first electrode of the fourth transistor T4. The second electrode of the third transistor T3 may be connected to the second electrode of the first transistor T1.

The fourth transistor T4 may include a gate electrode, the first electrode, and a second electrode. A first initialization signal GIS may be applied to the gate electrode of the fourth transistor T4. The first electrode of the fourth transistor T4 may be connected to the node N1, which connects to the first electrode of the third transistor T3. An initialization voltage VINIT may be applied to the second electrode of the fourth transistor T4.

The fifth transistor T5 may include a gate electrode, a first electrode, and the second electrode. An emission control signal EM may be applied to the gate electrode of the fifth transistor T5. A first power voltage ELVDD may be applied to the first electrode of the fifth transistor T5. The second electrode of the fifth transistor T5 may be connected to the first electrode of the first transistor T1.

The sixth transistor T6 may include a gate electrode, the first electrode, and a second electrode. The emission control signal EM may be applied to the gate electrode of the sixth transistor T6. The first electrode of the sixth transistor T6 may be connected to the second electrode of the first transistor T1. The second electrode of the sixth transistor T6 may be connected to a second electrode of the seventh transistor T7 and a first electrode of the light emitting diode LED.

The seventh transistor T7 may include a gate electrode, a first electrode, and the second electrode. A second initialization signal GB may be applied to the gate electrode of the seventh transistor T7. The initialization voltage VINIT may be applied to the first electrode of the seventh transistor T7. The second electrode of the seventh transistor T7 may be connected to the second electrode of the sixth transistor T6 and the first electrode of the light emitting diode LED.

The capacitor CST may include a first electrode and the second electrode. The first power voltage ELVDD may be applied to the first electrode of the capacitor CST. The second electrode of the capacitor CST may be connected to the node N1, which connects to the first electrode of the third transistor T3.

The light emitting diode LED may include the first electrode and a second electrode. The first electrode of the light emitting diode LED may be connected to the second electrode of the seventh transistor T7. A second power supply voltage ELVSS may be applied to the second electrode of the light emitting diode LED.

FIG. 8 illustrates an embodiment in which the pixel PX includes seven-transistors and one capacitor structure, sometimes referred to herein as a 7TIC structure. Meanwhile, in FIG. 2 of this specification, each of the pixels PX may have a 7TIC structure, but the embodiments of the present disclosure are not necessarily limited thereto. Each pixel PX may be configured in various ways, such as a 4T2C structure containing four transistors and two capacitors, a 5T2C structure containing five transistors and two capacitors, a 6T2C structure containing six transistors and two capacitors, a 7T2C structure containing seven transistors and two capacitors, or an 8TIC structure containing eight transistors and one capacitor.

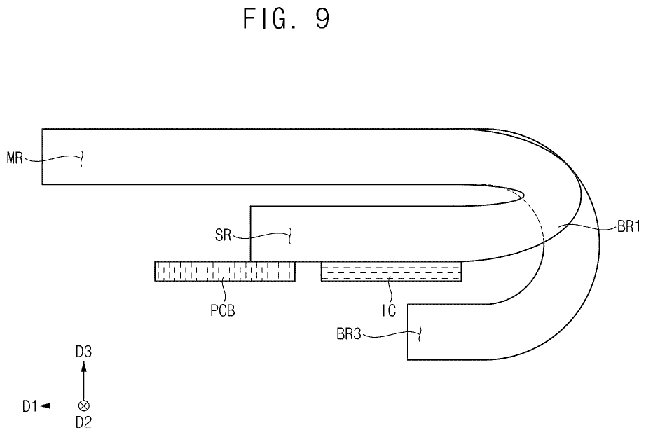

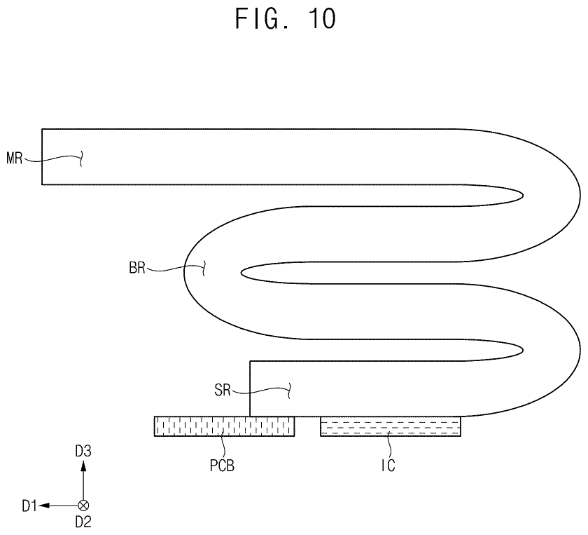

FIG. 9 is a cross-sectional view showing a bent portion of an embodiment of the display device of FIG. 3. FIG. 10 is a cross-sectional view showing another bent portion of an embodiment of the display device of FIG. 3.

Referring to FIGS. 3, 9, and 10, when the display device DD is bent, the bending areas BR may overlap the main area MR in a plan view. That is, when bending the display device DD along the bending lines BL of the bending areas BR, at least one bending area of the bending areas BR may overlap with the main area MR in a plan view. As the bending areas BR are bent, an area of a dead space, e.g., a plan-view area where an image is not displayed, on the display device DD may be reduced.

In an embodiment, when the display device DD is bent, at least one of the bending areas BR may be located below the sub area SR as shown in the cross-sectional view of FIG. 9. For example, the second bending area BR2 and the third bending area BR3 may extend below the sub area SR, which is below the main area MR. That is, portions of the second bending area BR2 and the third bending area BR3 may be located the driver IC and the printed circuit board PCB, which are on or connect to the sub area SR.

In an embodiment, when the display device DD is bent, at least a portion of one or more of the bending areas BR may be located between the main area MR and the sub area SR as shown in the cross-sectional view of FIG. 10. For example, portions of the second bending area BR2 and the third bending area BR3 may be located between the main area MR and the sub area SR. That is, the second bending area BR2 and the third bending area BR3 may be extend between the display panel DP and the driver IC.

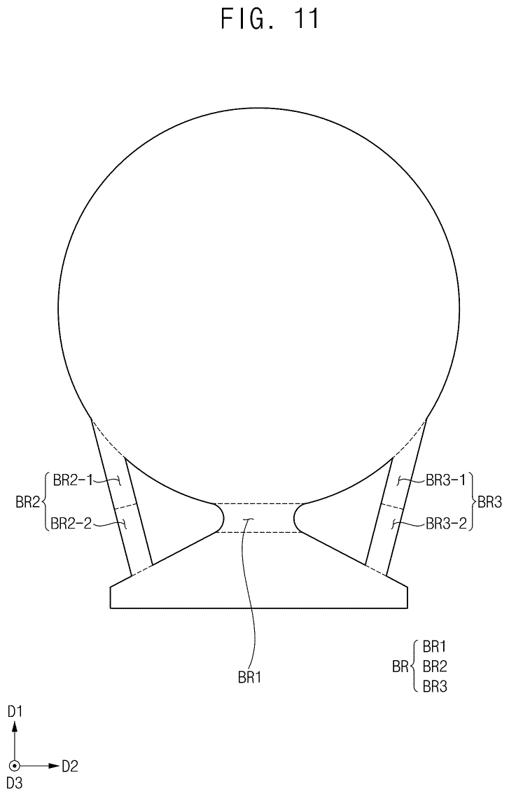

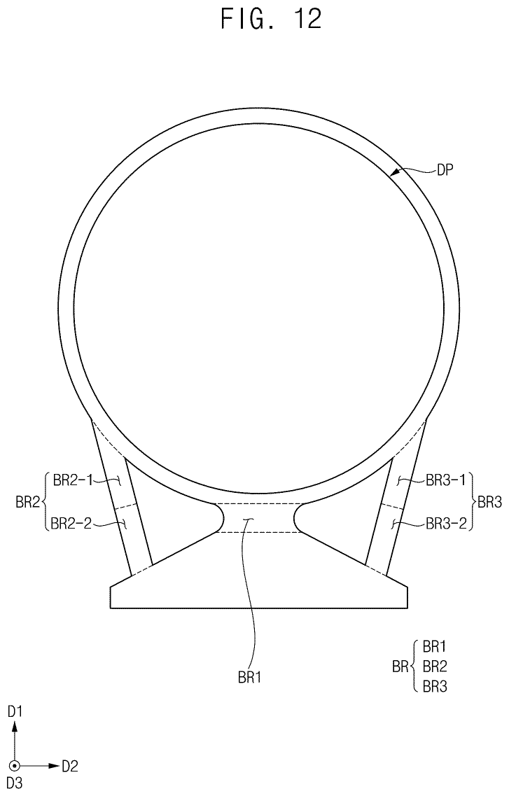

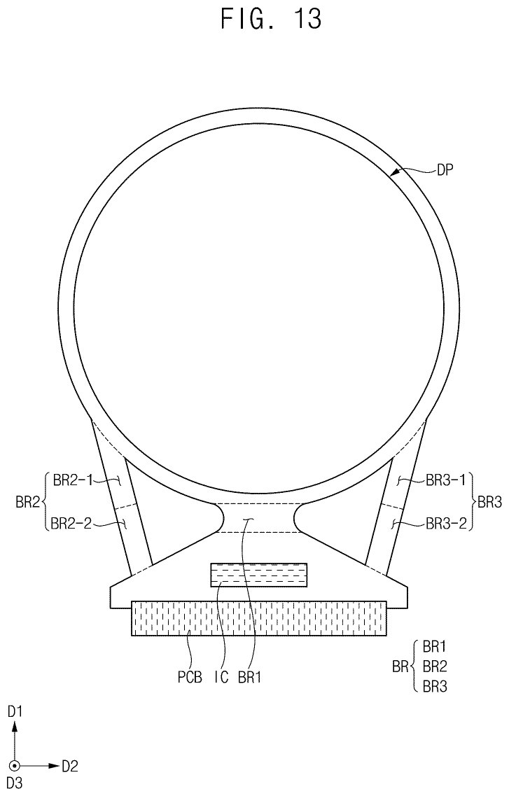

FIGS. 11 to 15 show structures created during an embodiment of a method of manufacturing the display device of FIG. 1.

Referring to FIGS. 11 to 13, the substrate SUB including a plurality of bending areas BR connecting the main area MR and the sub area SR may be provided. The substrate may be substantially flat as shown in FIG. 11. Thereafter, the display panel DP may be formed in the main area MR of the display device DD. The driver IC and the printed circuit board PCB may be formed in or connected to the sub area SR of the display device DD.

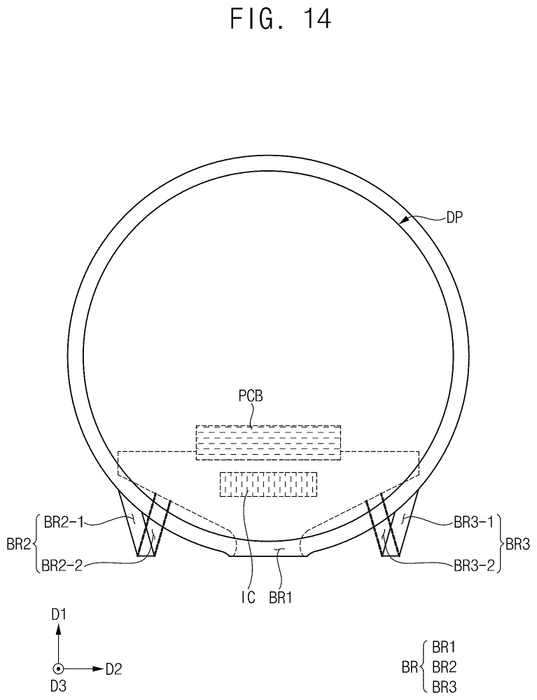

Referring further to FIGS. 2 and 14, the substrate SUB may be bent along the bending lines BL. For example, the first bending area BR1 may be bent along the 1-1th bending line BL1-1 and the 1-2th bending line BL1-2, and the second bending area BR2 may be bent along the 2-2th bending line BL2-2, and the third bending area BR3 may be bent along the 3-2th bending line BL3-2.

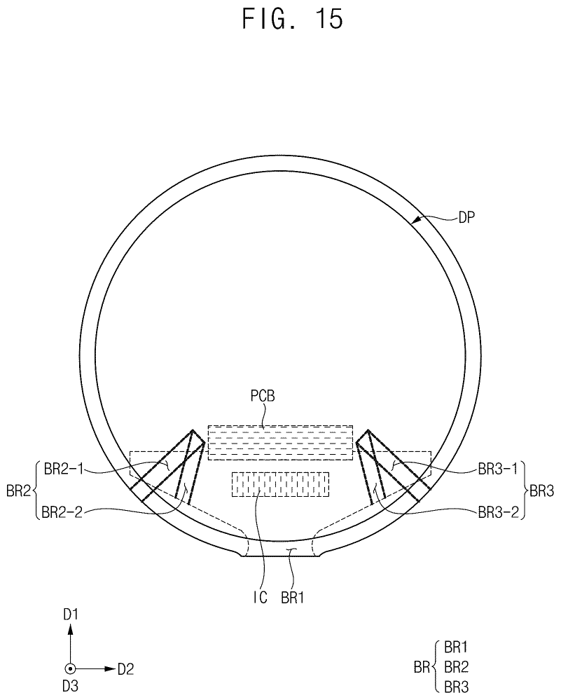

Referring further to FIGS. 2 and 15, the second bending area BR2 and the third bending area BR3 may be bent once more and below the main area MR. That is, the second bending area BR2 and the third bending area BR3 may be bent two or more times. Specifically, the second bending area BR2 may be bent along the 2-1 bending line BL2-1 and the 2-3th bending line BL2-3. The third bending area BR3 may be bent along the 3-1th bending line BL3-1 and the 3-3th bending line BL3-3.

In an embodiment, as described with reference to FIG. 9, the second bending area BR2 and the third bending area BR3 may be below the sub area SR. In another embodiment, as described with reference to FIG. 10, the second bending area BR2 and the third bending area BR3 are between the main area MR and the sub area SR. That is, each of the sub area SR and the bending areas BR may be bent to at least partially overlap the main area MR in a plan view.

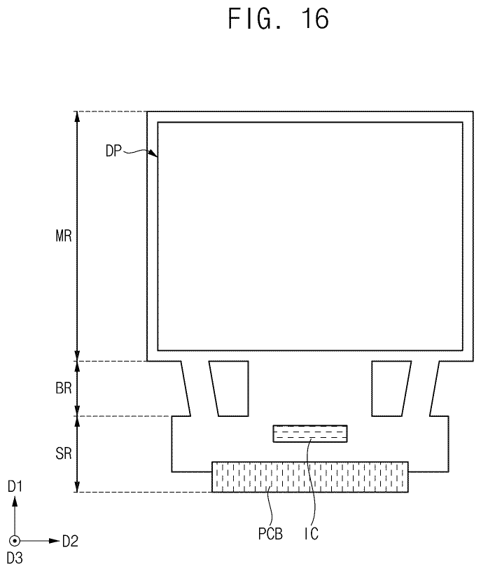

FIG. 16 is a plan view showing a display device according to another embodiment of the present disclosure.

Referring to FIG. 16, the display panel DP in the main area MR may have a rectangular shape in a plan view. However, embodiments of the present disclosure are not necessarily limited thereto. As described with reference to FIGS. 2 and 16, the display panel DP may have various shapes such as circular, square, oval, and diamond shapes depending on a user's needs.

The present disclosure may be applied to a display device and an electronic device including the same. For example, the present disclosure may be applied to high-resolution smartphones, mobile phones, smart pads, smart watches, tablet PCs, vehicle navigation systems, televisions, computer monitors, laptops, etc.

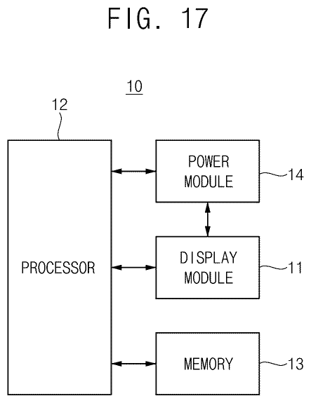

FIG. 17 is a block-diagram of an electronic device according to an embodiment of the disclosure.

Referring to FIG. 1 and FIG. 17, the display device DD according to the embodiments of present disclosure may be applied to various electronic devices 10. The electronic device 10 according to an embodiment may include the display device DD, and may further include a module or device including additional functions in addition to the display device DD.

The electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for operation of the processor 12 or the display module 11. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device, and a power conversion module that converts a power supplied by the power supply module to generate power necessary for an operation of the electronic device 10.

At least one of the components of the electronic device 10 described above may be included in the display device according to the embodiments described above. In addition, some of individual modules functionally included in one module may be included in the display device, and other parts may be provided separately from the display device. For example, the display device DD may include the display module 11, and the processor 12, the memory 13, and the power module 14 may be provided in the form of other devices within the electronic device 10 other than the display device DD.

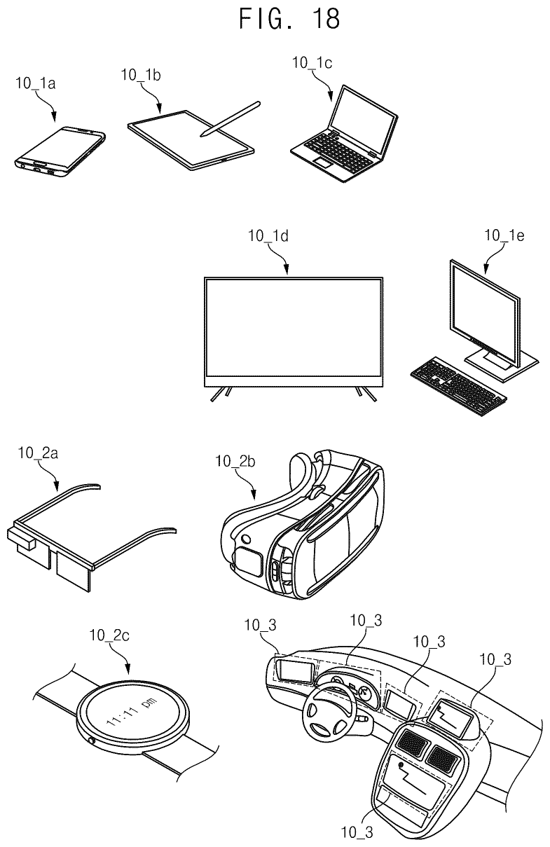

FIG. 18 shows schematic views of electronic devices according to various embodiments of FIG. 17.

Referring to FIGS. 17 and 18, various electronic devices to which the display device DD according to embodiments is applied may include not only image display electronic devices such as a smart phone 10_1a, a tablet PC 10_1b, a laptop 10_1c, a TV 10_1d, and a desk monitor 10_1e, but also wearable electronic devices including display modules such as smart glasses 10_2a, a head-mounted display 10_2b, and a smart watch 10_2c, and vehicle electronic devices 10_3 including display modules such as a CID (center information display) and a room mirror display placed on a dashboard, center fascia, or dashboard of an automobile.

However, this is exemplary, and the electronic device 10 according to embodiments of the present disclosure is not limited thereto. For example, the electronic device 10 may be implemented as a mobile phone, a video phone, a smart pad, a smart watch, a tablet PC, a vehicle display, a computer monitor, a notebook computer, a head-mounted display device, etc. In addition, the electronic device 10 may be a television, a monitor, a notebook computer, or a tablet. In addition, the electronic device 10 may be an automobile.

While the disclosure has been particularly shown and described with reference to embodiments thereof, those of ordinary skill in the art will understand that various changes in form and details may be made therein without departing from the spirit or scope of the disclosure as defined by the following claims.

What is claimed is:

1. A display device comprising:
a substrate including:
a main area including a display area,
a sub area spaced apart from the main area in a first direction, and
a plurality of bending areas connecting the main area and the sub area;
a display panel disposed in the display area on the substrate; and
a printed circuit board attached to the sub area.

2. The display device of claim 1, wherein the bending areas include a first bending area and a second bending area spaced apart from the first bending area in a second direction that differs from the first direction.

3. The display device of claim 2, wherein a width of the first bending area is greater than a width of the second bending area.

4. The display device of claim 2, further comprising:
first power wires extending from the printed circuit board and applying a first power source to the display panel; and
second power wires extending from the printed circuit board and applying a second power source different from the first power source to the display panel,
wherein each of the first power wires and the second power wires overlaps the bending areas.

5. The display device of claim 4, wherein each of the first power wires and the second power wires overlaps the first bending area.

6. The display device of claim 4, wherein the first power wires overlap the first bending area, and
the second power wires overlap the second bending area.

7. The display device of claim 4, wherein a voltage level of the first power source is greater than a voltage level of the second power source.

8. The display device of claim 2, wherein at least one of the bending areas includes three or more bending lines about which the at least one of bending areas is bent.

9. The display device of claim 8, wherein the first bending area includes
a first bending line;
a second bending line spaced apart from the first bending line; and
a third bending line between the first bending line and the second bending line, and
wherein the first bending line and the second bending line do not overlap in a plan view.

10. The display device of claim 1, further comprising:
a driver disposed in the sub area and driving the display panel, and
wherein the driver is mounted in the sub area as a chip-on plastic (COP) structure.

11. The display device of claim 1, wherein each of the sub area and the bending areas at least partially overlaps the main area in a plan view.

12. The display device of claim 11, wherein at least one of the bending areas is between the main area and the sub area.

13. The display device of claim 11, wherein at least one of the bending areas is below the sub area.

14. The display device of claim 1, wherein the substrate includes plastic.

15. The display device of claim 1, wherein the display panel has a circular shape in a plan view.

16. The display device of claim 13, wherein the display panel has a square shape in a plan view.

17. A method of the display device comprising:
providing a substrate including:
a main area including a display area,
a sub area spaced apart from one side of the main area, and
a plurality of bending areas connecting the main area and the sub area;
forming a display panel in the display area of the substrate;
attaching a printed circuit board to the sub area; and
bending the bending areas.

18. The method of claim 17, wherein, among the bending areas, at least one of the bending areas is bent two or more times.

19. The method of claim 17, wherein each of the sub area and the bending areas is bent to at least partially overlap the main area in a plan view.

20. The method of claim 17, wherein at least one of the bending areas includes
a first bending line;
a second bending line spaced apart from the first bending line; and
a third bending line between the first bending line and the second bending line, and
wherein the first bending line and the second bending line are bent so as not to overlap in a plan view.

21. An electronic device comprising:
a display device; and
a processor configured to drive the display device, and
wherein the display device includes:
a substrate including:
a main area including a display area.
a sub area spaced apart from the main area in a first direction, and
a plurality of bending areas connecting the main area and the sub area;
a display panel disposed in the display area on the substrate; and
a printed circuit board attached to the sub area.
